(19) United States
(12) Patent Application Publication
(10) Pub. No.: US 2012/0032212 A1
(43) Pub. Date: Feb. 9, 2012

(54) METHOD OF LIGHT EMITTING DIODE SIDEWALL PASSIVATION

(75) Inventors: Hung-Wen HUANG, Hsinchu City (TW); Hsing-Kuo HSIA, Jhubei City (TW); Ching-Hua CHIU, Hsinchu City (TW)

(73) Assignee: TAIWAN SEMICONDUCTOR MANUFACTURING COMPANY, LTD., Hsinchu (TW)

(21) Appl. No.: 12/851,696

(22) Filed: Aug. 6, 2010

(51) Int. Cl. H01L 33/58; H01L 21/30

(52) U.S. Cl. 257/98; 438/16; 257/E33.074; 257/E21.211

(57) ABSTRACT

A Light-Emitting Diode (LED) includes a light-emitting structure having a passivation layer disposed on vertical sidewalls across a first doped layer, an active layer, and a second doped layer that completely covers at least the sidewalls of the active layer. The passivation layer is formed by plasma bombardment or ion implantation of the light-emitting structure. It protects the sidewalls during subsequent processing steps and prevents current leakage around the active layer.

### TECHNICAL FIELD

The present disclosure relates generally to semiconductor light sources, and more particularly, to light-emitting diodes (LEDs).

### BACKGROUND

A Light-Emitting Diode (LED), as used herein, is a semiconductor light source including a semiconductor diode, electrical contacts, and optionally a bonding substrate, for generating a light at a specified wavelength or a range of wavelengths. LEDs are traditionally used for indicator lamps, and are increasingly used for displays. An LED emits light when a voltage is applied across a p-n junction of the semiconductor diode formed by oppositely doping semiconductor compound layers. Different wavelengths of light can be generated by varying the bandgaps of the semiconductor layers in the diode and by fabricating an active layer within the p-n junction. Additionally, an optional phosphor material changes the properties of light generated by the LED.

Continued development in LEDs has resulted in efficient and mechanically robust light sources that can produce light in the visible spectrum and beyond. These attributes, coupled with the potentially long service life of solid state devices, may enable a variety of new display applications, and may place LEDs in a position to compete with the well entrenched incandescent and fluorescent light sources. However, improvements in manufacturing processes to make highly efficient and mechanically robust LEDs continue to be sought.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIGS. 1 and 2A-2C are flowcharts illustrating a method of fabricating a Light-Emitting Diode (LED) according to some embodiments;

FIGS. 3-14 illustrate various views of the LED at various stages of fabrication according to certain embodiments of the present disclosure corresponding to the flowchart of FIG. 2A;

FIGS. 15-19 illustrate various views of the LED at various stages of fabrication according to certain embodiments of the present disclosure corresponding to the flowchart of FIG. 2B; and

FIGS. 20-32 illustrate various views of the LED at various stages of fabrication according to certain embodiments of the present disclosure corresponding to the flowchart of FIG. 2C.

### DETAILED DESCRIPTION

It is understood that the following disclosure provides many different embodiments, or examples, for implementing different features of various embodiments. Specific examples of components and arrangements are described below to simplify the present disclosure. These are merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

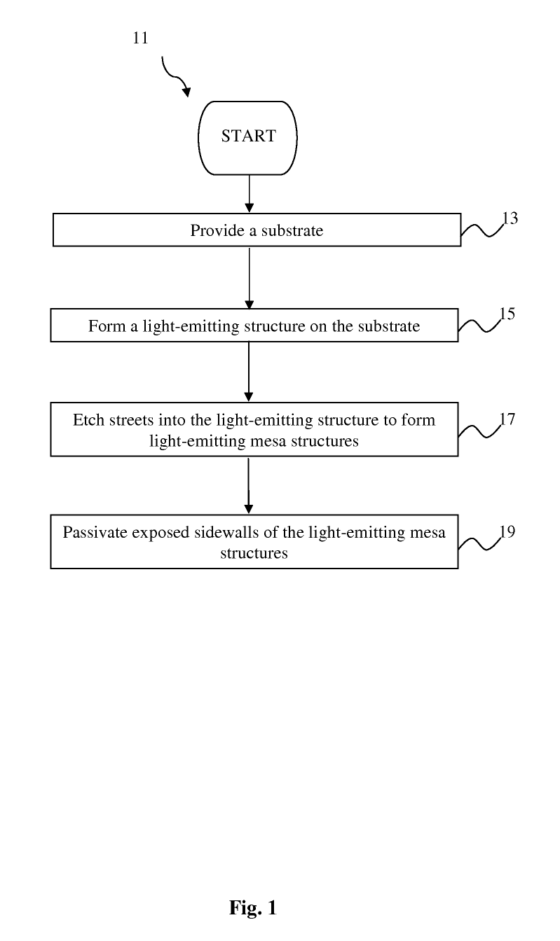

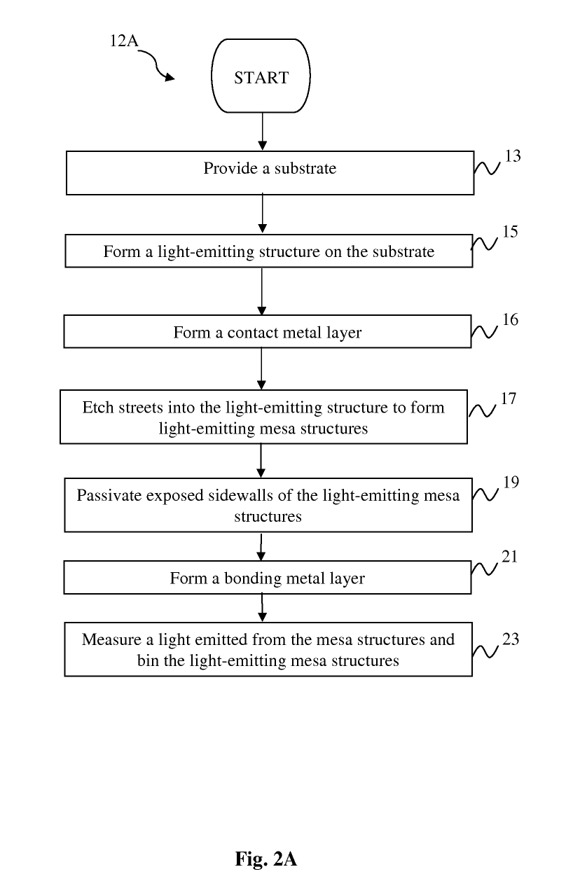

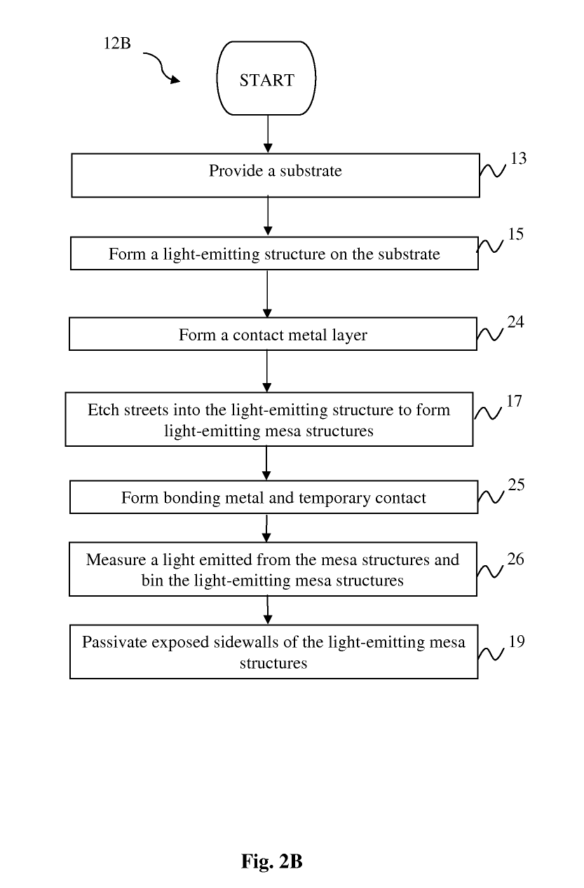

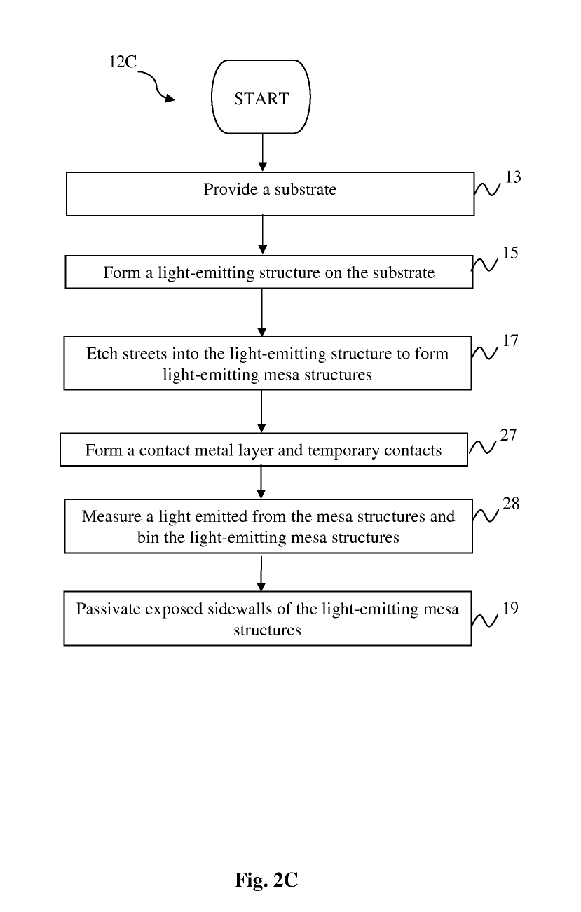

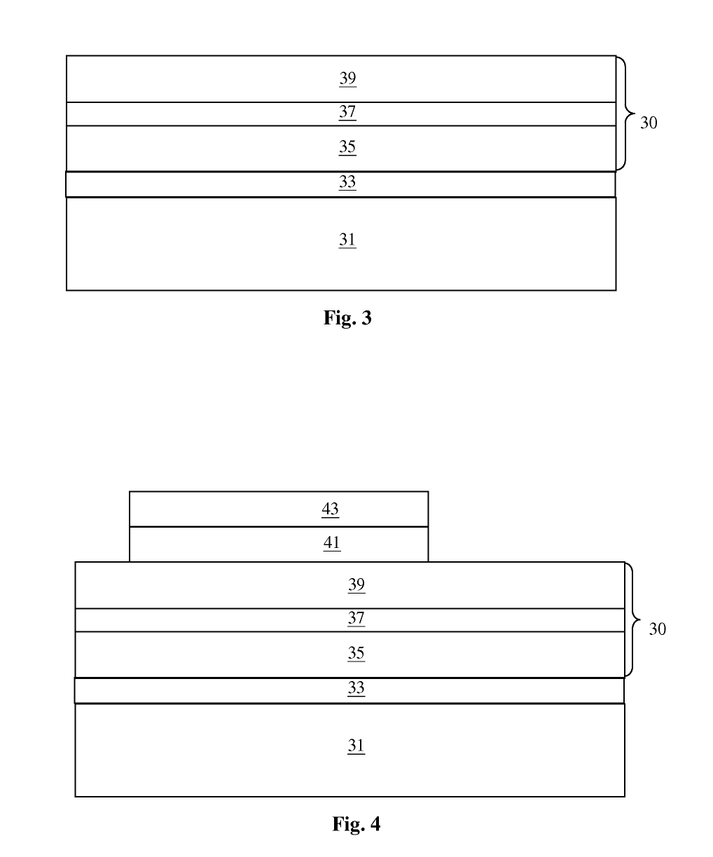

Illustrated in FIGS. 1 and 2A-2C are flowcharts of methods 11 and 12A to 12C for fabricating a Light-Emitting Diode (LED) in accordance with some embodiments of the present disclosure. FIG. 1 illustrates generalized operations that are performed with one or more embodiments of the disclosure. FIGS. 2A to 2C illustrate different embodiments that include all or at least a portion of the generalized operations of FIG. 1. When operations of FIG. 1 are performed in FIG. 2A to 2C, the operation is labeled with the same element number. The operations of FIG. 1 are first discussed in detail with reference to various cross-section FIGS. 3-7. The different embodiments of FIG. 2A to 2C are then discussed.

An LED may be a part of a display or lighting device having a number of the LEDs, the LEDs in the device being either controlled singly or in combination. The LED may also be a part of an integrated circuit (IC) chip, system on chip (SoC), or portion thereof, that may include various passive and active microelectronic devices such as resistors, capacitors, inductors, diodes, metal-oxide semiconductor field effect transistors (MOSFET), complementary metal-oxide semiconductor (CMOS) transistors, bipolar junction transistors (BJT), laterally diffused MOS (LDMOS) transistors, high power MOS transistors, or other types of transistors. It is understood that various figures have been simplified for a better understanding of the present disclosure. Accordingly, it should be noted that additional processes may be provided before, during, and after the methods of FIGS. 1 and 2A to 2C, that some other processes may only be briefly described, and various applicable processes may be substituted for the described processes to achieve the same effect.

Referring to FIG. 1, the method 11 begins with operation 13 in which a substrate is provided. The substrate includes a material that is suitable for growing a light-emitting structure. Thus, the substrate may also be referred to as a growth substrate or a growth wafer. In one embodiment, the substrate is sapphire. In some other embodiments, the substrate may be silicon carbide, silicon, or another suitable material for growing the light-emitting structure. A light-emitting structure is formed on the substrate in operation 15. The light-emitting structure is usually a semiconductor diode.

FIG. 3 shows a light-emitting structure 30 formed over the substrate 31. A light-emitting structure 30 is formed over the substrate 31. In the present embodiment, the light-emitting structure 30 includes a doped layer 35, a multiple quantum well layer (MQW) 37, and a doped layer 39. The doped layers 35 and 39 are oppositely doped semiconductor layers. In some embodiments, the doped layer 35 includes an n-type gallium nitride material, and the doped layer 39 includes a p-type gallium nitride material. In some other embodiments, the doped layer 35 may include a p-type gallium nitride material, and the doped layer 39 may include an n-type gallium nitride material. The MQW layer 37 shown in FIG. 3 includes alternating (or periodic) layers of active material, for example, gallium nitride and indium gallium nitride. For example, in one embodiment, the MQW layer 37 includes ten layers of gallium nitride and ten layers of indium gallium nitride, where an indium gallium nitride layer is formed on a gallium nitride layer, and another gallium nitride layer is formed on the indium gallium nitride layer, and so on and so forth. The light emission efficiency of the structure depends on the number of layers of alternating layers and their thicknesses. In various embodiments, the thickness of the MQW layer 37 may be about 10-2000 nm, about 100-1000 nm, about 1 μm, or for example, about 100 nm.

In some embodiments according to FIG. 3, the doped layer 35, the MQW layer 37, and the doped layer 39 are all formed by epitaxial growth processes. In the epitaxial growth processes, a first undoped layer 33, usually gallium nitride and may be aluminum nitride, is grown on the substrate 31. The first undoped layer 33 is also referred to as a buffer layer 33. The buffer layer may be about 500 nm to 5 μm, for example, about 2 μm. The layers 35, 37, and 39 are epitaxially grown on the buffer layer 33. The doping may be accomplished by adding impurities into a source gas during the epitaxial growth process or by other commonly used doping processes. After the completion of the epitaxial growth process, a p-n junction (or a p-n diode) is essentially formed with the MQW layer 37 formed between the doped layer 35 and the doped layer 39. When an electrical voltage is applied between the doped layer 35 and the doped layer 39, an electrical current flows through the light-emitting structure 30 and the MQW layer 37 emits radiation. The color of the light emitted by the MQW layer 37 is determined by the wavelength of the emitted radiation, which may be tuned by varying the composition and structure of the materials that make up the MQW layer 37. For example, a small increase in the concentration of indium in the indium gallium nitride layer is associated with a shift of the light's wavelength output toward longer wavelengths.

The operation of forming a light-emitting structure 30 may optionally include the formation of additional layers not shown in FIG. 3. For example, an ohmic contact layer or other layers may be added on the doped layer 39. These other layers may be an indium tin oxide (ITO) layer, or another transparent conductive layer.

Referring back to FIG. 1, streets are etched into the light-emitting structure to form light-emitting mesa structures in operation 17. FIG. 6 shows the streets 47 etched to the light-emitting structure 30. The streets 47 separate individual light-emitting mesa structures. While the streets are shown as having high aspect ratios, the drawings are not to scale and in reality the streets may be much wider than they appear. The mesa structure may be a total of several microns high and hundreds or thousands of microns wide. The street width may be more than 50 microns wide. As shown, the etching that forms the streets 47 stops at about the interface between the buffer layer 33 and the doped layer 35. In various embodiments, the etch stops at somewhere past the interface in the buffer layer 33, or before the interface in the first doped layer 35. Preferably, the etch stops at or past the interface of the buffer layer 33 and the doped layer 35, but leaving a portion of buffer layer 33 to conduct current during subsequent testing and binning. In some embodiments, the depth of the etching may be controlled by various process parameters such as duration or selectivity of the materials or reactants.

The light-emitting mesa structure etch may be a dry etch or a wet etch. For dry etching, an inductively coupled plasma may be used with argon or nitrogen plasma. For wet etching, HCl, HF, HI, H₂SO₄, H₂PO₄, H₃PO₄, C₆H₈O₇, or a combination of these sequentially may be used. Some wet etchants require a higher temperature to reach a good etch rate, such as phosphoric acid with etching temperature of about 50° C. to about 100° C.

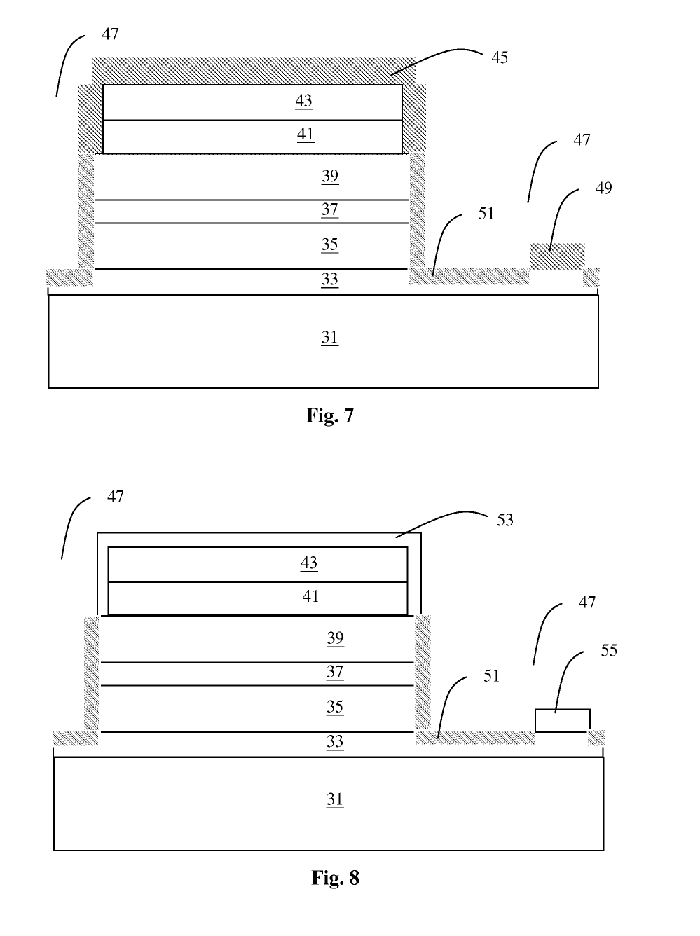

Referring back to FIG. 1, exposed sidewalls of the light-emitting mesa structures and portions of the street 47 surface are then passivated in operation 19. The passivated portion is shown as element 51 in FIG. 7.

The passivating operation uses plasma bombardment or, in some alternative embodiments, an ion implantation process. A plasma bombardment process uses nitrogen, argon, krypton, oxygen, and/or other known passivating agents. The plasma is produced in situ in the process chamber or remotely and flowed to the chamber. Various applicable methods to produce plasma may be used, including capacitively coupled plasma (CCP), inductively coupled plasma (ICP), magnetron plasma, electron cyclotron resonance (ECR), or microwave. The plasma may have high ion density. The plasma bombardment operation may be conducted at a substrate temperature of less than about 150° C., preferably at about room temperature. The use of plasma in semiconductor surface treatment process is well known in the art and details are not further described herein.

A photoresist pattern may cover the top surface of the doped layer 39 so only the sidewall portions of the light-emitting mesa structure are substantially exposed during the passivation operation. Thus the photoresist pattern can serve both the function of patterning for the mesa etch and for the sidewall passivation. To avoid a leakage current around the MQW layer, it is particularly important to passivate the sidewall at the MQW layer 37 and its adjacent layers, i.e. doped layers 35 and 39. Passivating a greater area along the sidewalls is beneficial because it decreases the likelihood that subsequent etching processes harm the light-emitting structure. The passivation layer may include a passivated first doped layer (passivated at edges of layer 35), a passivated active layer (MQW layer) (passivated at edges of layer 37), and a passivated second doped layer (passivated at edges of layer 39). The passivated portion of the light-emitting structure from the edge toward a center line of the light-emitting mesa structure (depth of passivation) may be about 500 angstroms, or at least 100 angstroms, and may be as much as 200 nm, depending on the type of plasma and bias used.

In some embodiments, methods of passivating the MQW sidewall includes depositing a dielectric layer, such as silicon oxide or silicon nitride, using plasma enhanced chemical vapor deposition (PECVD). PECVD is used because some other dielectric deposition techniques uses a higher temperature, which may cause problems with the metals layers 41 and 43 previously deposited. In some other embodiments, a high dielectric deposition temperature may interfere with a metal adhesion layer. While PECVD allows a lower substrate temperature, the silicon oxide film it deposits does not cover the mesa sidewall well because these mesa sidewalls are much higher than sidewalls in semiconductor circuit fabrication where the PECVD is typically used. At a mesa sidewall height of around 4 μm, current leakage path may exist around the mesa periphery and adhesion issues may exist.

The passivation layer 51 in the present disclosure is highly conformal because it is created from the light-emitting structure itself. The passivation layer 51 includes no silicon oxide. The passivation layer can be made uniform on the mesa sidewall by tuning the plasma process. There is no interface between the passivation layer 51 and the active portions (light emitting) of the light-emitting structure, circumventing any adhesion issues. As result, the passivation layer 51 thus created is believed to provide better passivation and protection than traditional PECVD silicon oxide material.

In some other embodiments, the passivation layer is formed using an ion implantation process. Ion implantation is performed on the substrate using nitrogen, argon, krypton, oxygen, silicon, selenium, beryllium, chlorine, boron, fluorine, boron fluoride, and/or other suitable materials. For example, nitrogen is implanted at energy of 20 keV to 150 keV at a dosage of 10¹³ cm.⁻² to 10¹⁴ cm.⁻². The sidewise depth of the light-emitting structure that is passivated may be about 50 nm, or at least 10 nm, and may be as much as 200 nm depending on the energy of the implantation process.

The operations of FIG. 1 are applied in various example embodiments discussed herein with reference to FIGS. 2A to 2C and various cross-section Figures. FIG. 2A is a process flow diagram of an example flow 12A in accordance with various embodiments of the present disclosure. Operations 13 and 15 are discussed above. In operation 13, a substrate such as a sapphire growth substrate is provided. In operation 15, a light-emitting structure is formed on the substrate.

Then a contact metal layer is formed on the light-emitting structure, and a bonding metal layer is formed over the contact metal layer, in operation 16. FIG. 4 shows a contact metal layer 41 and optionally a reflecting metal layer 43 formed on the light-emitting structure 30. The contact metal layer 41 is a metal, which may be nickel, an alloy of nickel, or some other metal. In at least one embodiment, the contact metal layer 41 is a nickel/silver alloy. The contact metal layer 41 adheres well to the top layer of the light-emitting structure 30, which may be the doped layer 39 or the optional ohmic contact, and the reflecting metal layer 43. A light reflecting layer 43 may be a metal, such as aluminum, copper, titanium, silver, gold, alloys of these such as titanium/platinum/gold, or combinations thereof. Particularly, silver and aluminum are known to be good reflectors of blue light. The light-reflecting layer may be formed by a physical vapor deposition (PVD) process, a chemical vapor deposition (CVD), an electroplating process, or other applicable deposition processes. Together, the contact metal layer 41 and the reflecting metal layer 43 may have a thickness about 300 nm.

As noted above, a reflecting metal layer may be disposed between the contact metal layer and the bonding metal layer. The contact metal layer 41 and the optional bonding metal layer 43 are deposited using the same pattern using a PVD process, an electroplating process, or a CVD process, or other applicable deposition processes. The layers may be deposited using different techniques. For example, layer 43 may be deposited using electrochemical plating while layer 41 may be deposited using PVD.

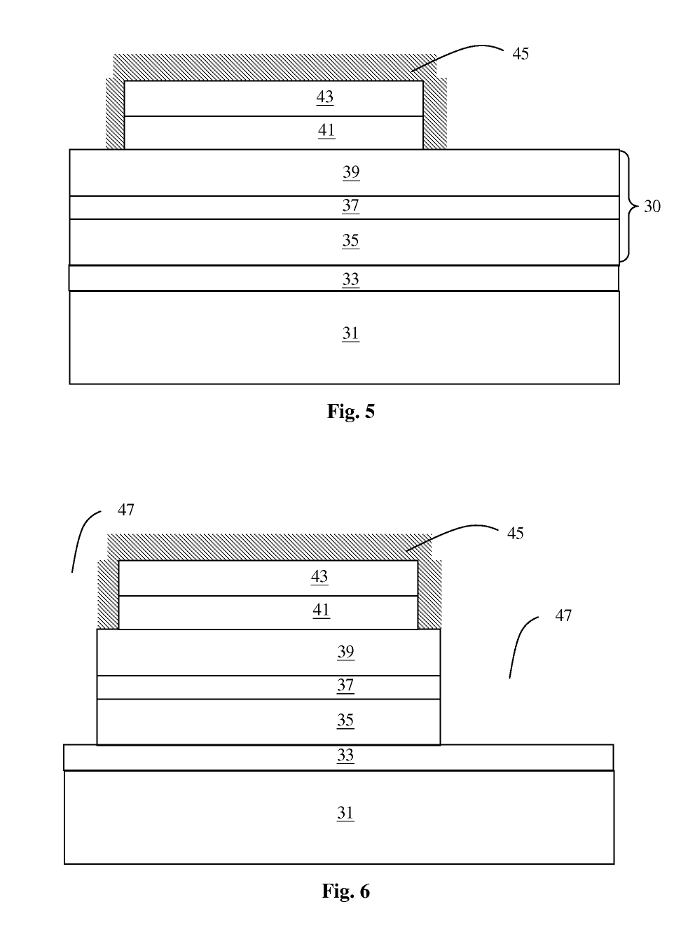

FIG. 5 shows a photoresist pattern 45 on and around the metal layers 41 and 43. The photoresist pattern 45 is deposited, exposed, and developed on the workpiece. The pattern defines an area around the metal layers 41 and 43. The structure is then etched using a scribe pattern to form light-emitting mesa structures as shown in FIG. 6 and in operation 17 of FIG. 2A, which is also discussed above with FIG. 1. In operation 19, the exposed sidewalls of the light-emitting mesa structures are passivated as shown in FIG. 7. A photoresist pattern 49 is added in one of the streets 47 region to protect a portion of the buffer layer 33.

A bonding metal layer is formed in operation 21 of FIG. 2A. FIG. 8 shows the addition of bonding metal layer 53 to the contact metal layer 41 and reflecting metal layer 43. After forming the passivation layer 51, the photoresist patterns 45 and 49 are removed or stripped and a new pattern is deposited for the bonding metal material deposition. The bonding metal may be deposited using PVD, CVD or other deposition process including electrodeposition or electroless deposition. The bonding metal material is also deposited to form a temporary contact 55. The bonding metal material may be a soft metal suitable for bonding with an adhesion metal layer on a bonding substrate. For example, the bonding metal may be gold, tin, or a eutectic gold/tin alloy.

The bonding metal layer 53 and the temporary contact 55 may be used to test the individual light-emitting mesa structure's light output given a particular current and/or voltage in a wafer-based binning process, shown as operation 23 of FIG. 2A. Electrodes are moved across the substrate from one light-emitting mesa structure to another light-emitting mesa structure. The light output at each light-emitting mesa structure is measured. At this stage, any defect in a light-emitting mesa structure causing light output that is below a minimum specification can be marked and removed from subsequent processing. When a defective light-emitting mesa structure is discovered much later in the LED fabrication process, the discard includes more material costs such as packaging, lens molding, and phosphor coating. Such early defective product removal saves manufacturing time and material costs. Light-emitting mesa structures with light outputs that meet the minimum specification are categorized into different bins of different output ranges for further manufacturing of products having different specifications.

Some LED applications require very narrow binning. In other words, the LEDs in the same bin must perform very similar to each other. One such application is the use of LEDs in television backlighting. Having one or two LEDs with a different light output may make a discernible difference in the performance of the television. On the other hand, one slightly lower output LED may make little or no difference in a streetlight. Early binning in this case also allows light-emitting mesa structures that are binned together to be packaged together.

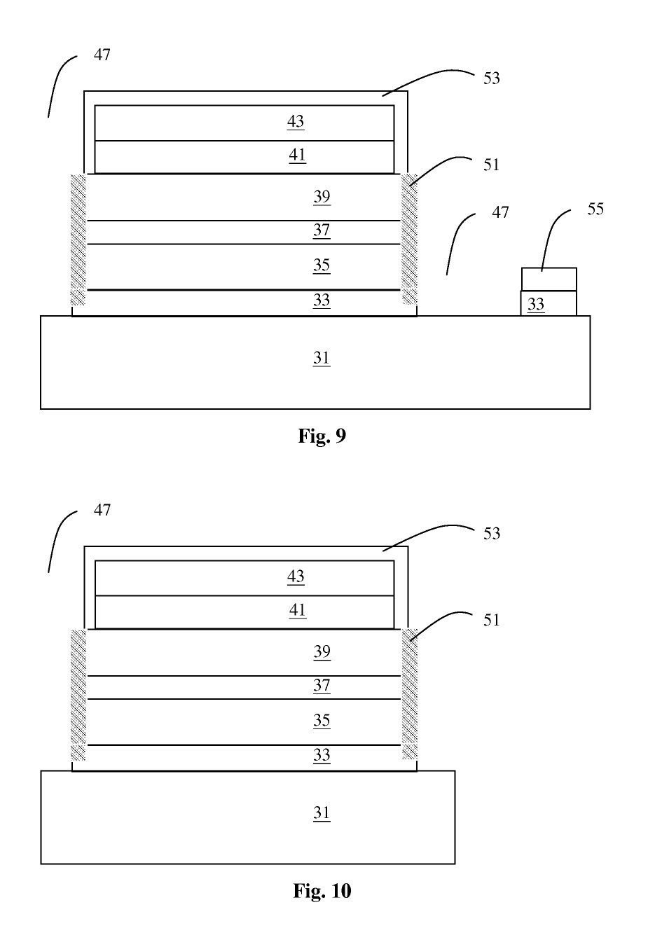

FIG. 9 shows a result of a second etching operation where the exposed portion of layer 33 in the streets 47 region is removed. For this second etch, the bonding metal layer 53 and temporary contact 55 may be used as mask and no photoresist patterning is necessary. In some embodiments, the second etch operation is optional. Inadvertent etching of the sidewalls is avoided by using ion inducement and specific chemistry to enhance the etch rate and promote the anisotropy. A bias may be applied to the substrate to direct reactive ions in the plasma toward horizontal portions of the surface.

After the light-emitting mesa structures are binned, they can be diced or separated into individual LED dies as shown in FIG. 10. The dicing process may be a non-etching process where a cutting device, such as a laser beam or a saw blade, is used to physically separate the light-emitting mesa structures into LED dies. After being diced, each LED die is capable of generating light and is physically and electrically independent from other dies.

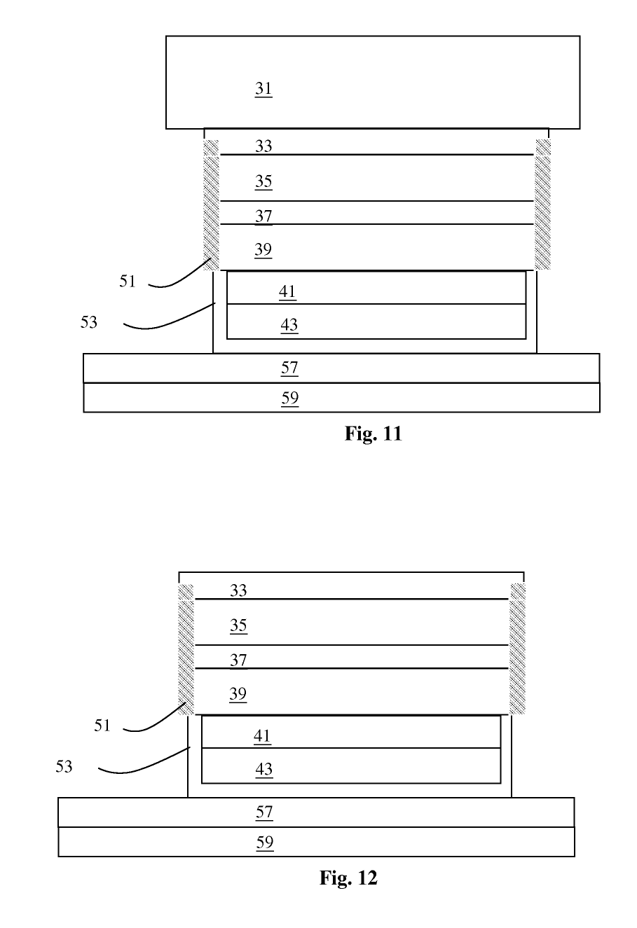

The LED dies are flipped over and bonded to a substrate 59 as shown in FIG. 11. The bonding metal layer 53 is bonded to an adhesion metal layer 57 on the substrate 59. Substrate 59 is usually a silicon substrate, but may also be metal or ceramic. A suitable substrate material has a high thermal conductivity, such as silicon and copper. The adhesion metal layer may be made of gold, tin, or an alloy of these. The bonding metal layer 53 and the adhesion metal layer 57 may be bonded via eutectic bonding or metal bonding. For eutectic bonding, the bonding metal layer 53 may be a gold/tin alloy and the adhesion metal layer may be made of gold. For metal bonding, both metal layers 53 and 57 may be gold.

After the LED dies are bonded to the substrate, the growth substrate 31 is removed. Various methods are applicable to remove the growth substrate. In one example, an interface between the growth substrate and the buffer layer 33 is treated with electromagnetic radiation (for example, laser), which decomposes the material, usually the buffer layer, at the interface. This interface may be doped or undoped gallium nitride layer. The growth substrate, for example, sapphire, may be lifted off and removed as shown in FIG. 12.

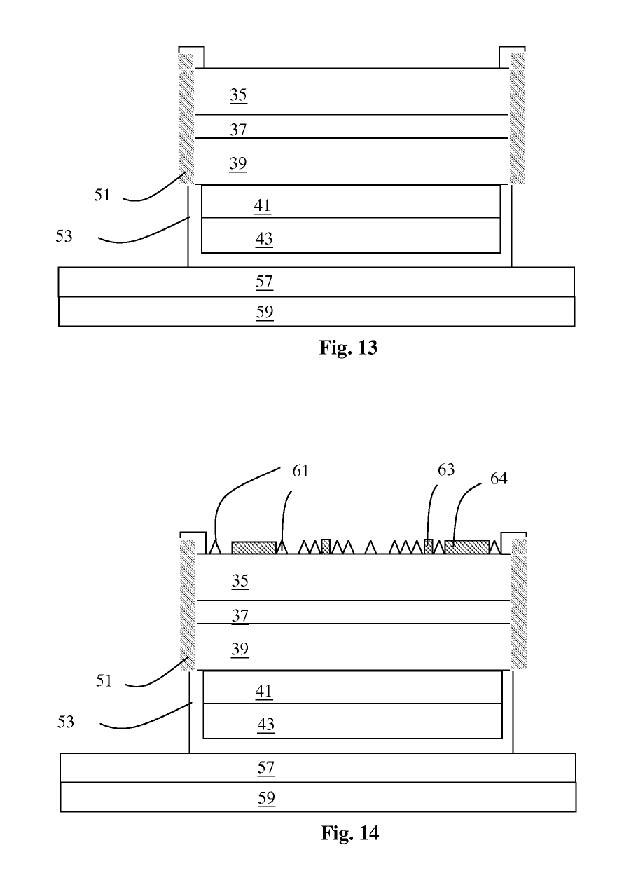

FIG. 13 shows the substrate mounted LED dies having a portion of the buffer layer 33 removed. A photoresist pattern (not shown) may be first applied to protect portions of the structure from the removal process. The photoresist pattern may be applied to the edges of the LED die, the passivation layer surface 51, and surfaces of the metal layers 53 and 57. A dry etch process may be employed, for example, inductively coupled plasma process to remove a portion of the buffer layer 33. Note that although FIG. 13 shows the edge of buffer layer 33 remaining on the LED die, it is not necessary that the edges remain. In the previous described embodiment, the edges are protected using a photoresist so as to not to remove the passivation layer 51. However, in some alternative embodiments, other methods to protect the passivation layer 51 may be used, such as depositing first a sacrificial layer on the sidewalls before removing the buffer layer. Generally, ICP with a bias to perform physical etching using heavier molecules, such as argon, krypton, or xenon, may be used to remove at least a portion of the buffer layer 33.

Referring to FIG. 14, the exposed surface of the first doped layer 35 is then treated to obtain a rough surface 61. In some embodiments, the surface is patterned first to protect areas on which metal contacts 63 and pads 64 are to be formed and then treated with plasma to form a rough surface. A plasma etch using chemical etchants such as chlorine is used to etch the surface along the gallium nitride crystal lattice structure, forming a rough surface having small triangular shapes. The roughened surface may then be patterned for the contact metal deposition. In certain embodiments, the contact metal is deposited to form an interconnect pattern on the die surface with thin contacts 63 with a number of contact pads 64. Such an interconnect structure spreads the current throughout the surface. The thin contacts 63 may be about 20 to about 30 μm wide, while the contact pads may be about 50 to 80 μm wide. Note that while a photoresist patterning step may be skipped by forming the contacts on a roughened surface or by subjecting the contact metal to plasma etching, the contact resistance may correspondingly increase.

FIG. 2B is a process flow diagram of an example flow 12B in accordance with various embodiments of the present disclosure. Operations 13 and 15 are discussed above. In operation 13, a substrate such as a sapphire growth substrate is provided. In operation 15, a light-emitting structure is formed on the substrate. Then a contact metal layer is formed on the light-emitting structure, in operation 24. The structure is then etched using a scribe pattern to form light-emitting mesa structures in operation 17. Bonding metal and temporary contacts are formed in the streets between the light-emitting mesa structures for testing and binning the individual structures in operation 25. During the testing and binning process of operation 26, a current is conducted across a light-emitting mesa structure and the resulting light output measured. A pair of electrode probes would contact the bonding metal and the temporary contact. The testing may include measuring different output in response of different current inputs. Light-emitting mesa structures that respond similarly are binned together and mounted onto the same substrate for packaging purposes. One skilled in the art may note that one temporary contact may be used for testing several adjacent light-emitting mesa structures when the structures are tested one at a time and have the same geometry. In operation 19, the exposed sidewalls of the light-emitting mesa structures are passivated after the streets are etched down to the substrate level.

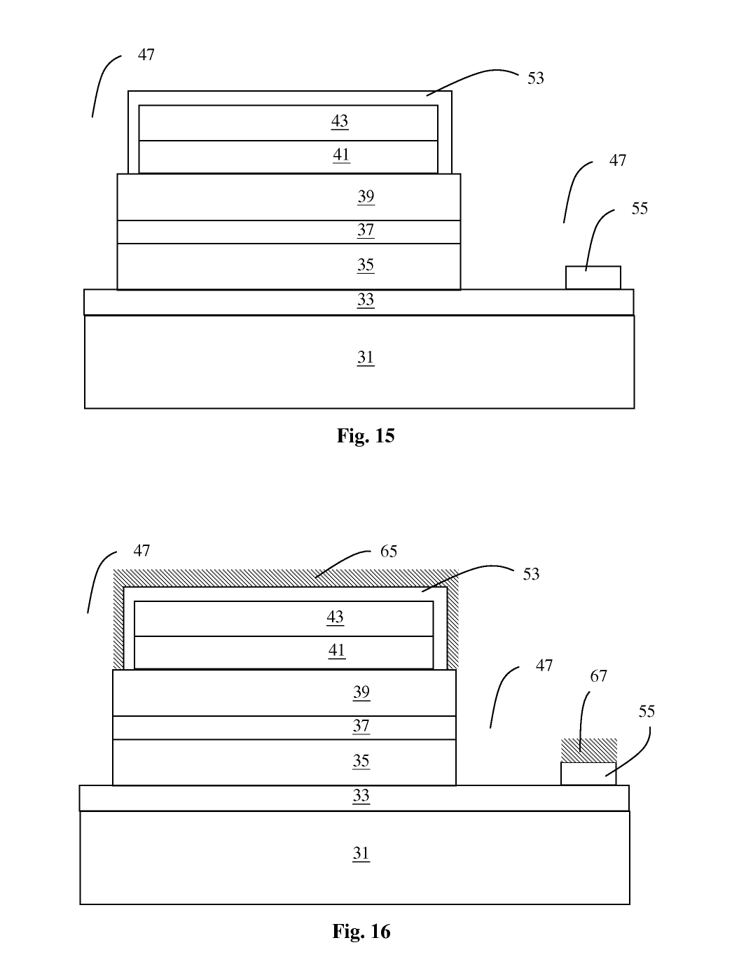

FIGS. 15 to 19, together with FIGS. 3 to 6 and 10 to 14, illustrate the intermediate structures of the process flow of FIG. 2B. FIGS. 3 to 6 depict forming the light-emitting structure 30 (FIG. 3), contact metal layer 41 and reflecting metal layer 43 (FIG. 4), and etching streets into the light-emitting structure forming light-emitting mesa structures (FIG. 6) as disclosed above.

In FIG. 15, a bonding metal layer 53 and a temporary contact 55 are formed on the partially fabricated LED in one operation using the same bonding metal material. As shown, the bonding metal layer 53 is formed around the metal layers 41 and 43. Prior to forming the bonding metal layer 53 and the temporary contact 55, the photoresist pattern 45 is removed and new pattern applied. The bonding metal material may be a soft metal suitable for bonding with an adhesion metal layer on a bonding substrate. For example, the bonding metal may be a eutectic gold/tin alloy. The bonding metal may be deposited using PVD, CVD or other deposition process including electrodeposition or electroless deposition.

The bonding metal layer 53 and the temporary contact 55 may be used to test the individual light-emitting mesa structure's light output given a particular current and/or voltage in a wafer-based binning process. Because the passivation layer has not formed at this stage of the process, and remaining process can still affect the final performance of the LED, the LEDs may be tested again later in the manufacturing process.

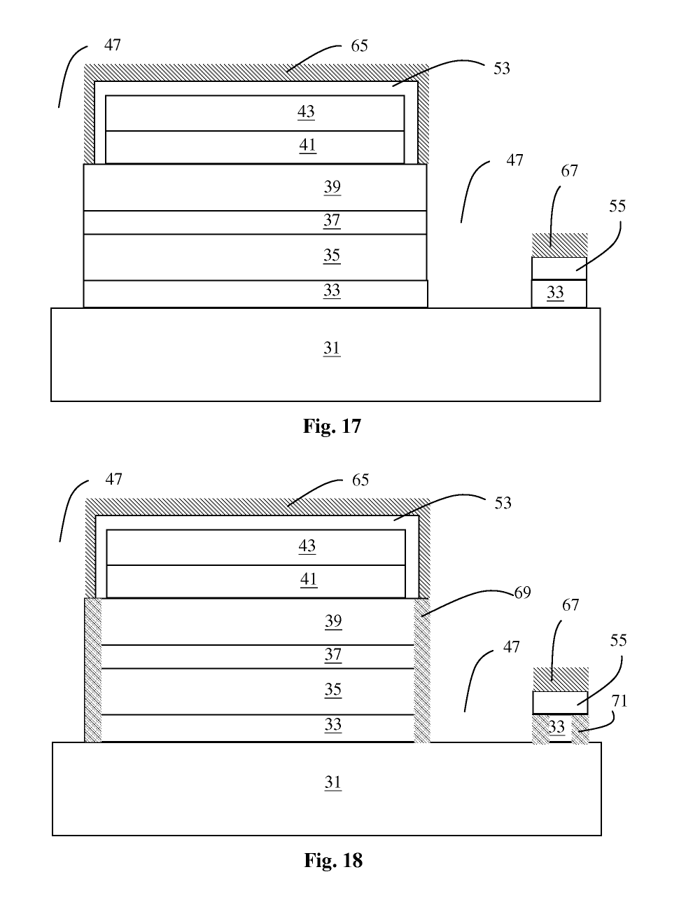

FIG. 16 shows a photoresist pattern 65 and 67 on the bonding metal layer 53 and temporary contact 55, respectively. The photoresist pattern 65 and 67 protects the metal layers from a second etch operation where a portion of layer 33 is removed. In some embodiments, the temporary metal contact 55 is not protected after the preliminary binning because the temporary metal contact is no longer needed. In certain embodiments, the bonding metal layer 53 and temporary contact 55 may be used as mask and no photoresist patterning is necessary. FIG. 17 shows the light-emitting mesa structure after the exposed portion of layer 33 is removed. The light-emitting mesa structure sidewalls are exposed down to the substrate 31. The exposed sidewalls are passivated in a passivation operation as described above relative to FIG. 7, creating a passivation layer shown as layer 69 in FIG. 18. In some embodiments, having the passivation layer extend all the way to the substrate 31 improves the passivation and protection.

In some embodiments, the etching of a portion of layer 33 and passivation of the sidewall to form passivation layer 69 are performed sequentially in the same chamber or at the same time. Plasma used to etch portions of layer 33 may be also used to passivate the sidewalls. In some embodiments, the process parameters are adjusted at the end of the etching operation to create the passivation surface, for example, by changing the gas source, changing gas flows, and/or plasma charge characteristics (RF power, etc.).

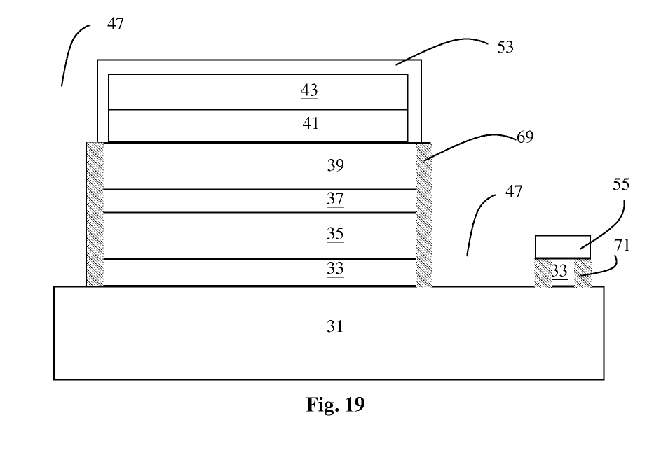

In some embodiments, the portions of layer 33 in the street region are not removed. These portions in the street region may be removed by a cutting device when the light-emitting mesa structures are separated from each other. FIG. 19 shows the partially fabricated LED with the photoresist pattern 65 removed.

The structure in FIG. 19 may undergo the subsequent processing steps shown in FIG. 10 through FIG. 14. The text associated with FIGS. 10 to 14 describes in detail the subsequent operations. In short, FIG. 10 shows an individual LED die after dicing or being separated. FIG. 11 shows an LED die that is flipped over and bonded to a substrate. After the LED dies are bonded to the substrate, the growth substrate 31 is removed as shown in FIG. 12. FIG. 13 shows the substrate mounted LED dies having a portion of the buffer layer 33 removed. FIG. 14 shows the result of treating the exposed surface of the first doped layer and forming the metal contacts.

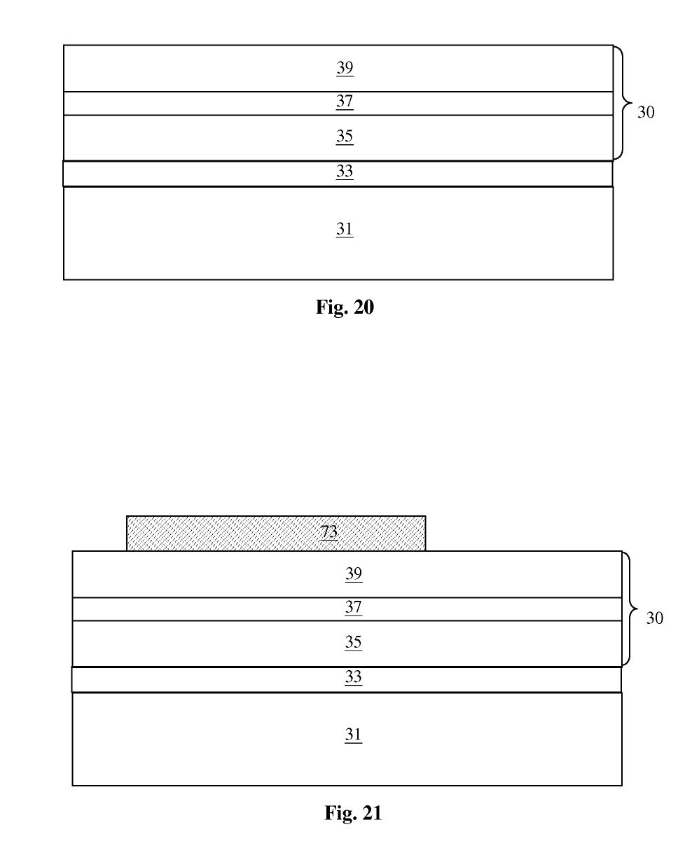

In yet some other embodiments, some of the photoresist patterning operations are combined into one operation to decrease manufacturing costs associated with mask making, depositing a photoresist, exposing the photoresist, developing the pattern, and forming the pattern. FIG. 2C illustrates operations of one such process with FIGS. 20 to 32 corresponding to the intermediate structures.

In operation 13, a substrate such as a sapphire growth substrate is provided. In operation 15, a light-emitting structure is formed on the substrate. FIG. 20 illustrates a light-emitting structure 30 is formed on a substrate 31. The light-emitting structure 30 includes a doped layer 35, a multiple quantum well layer (MQW) 37, and a doped layer 39. The doped layers 35 and 39 are oppositely doped semiconductor layers. The MQW layer 37 shown in FIG. 20 includes alternating (or periodic) layers, ten or more sets, of active material, for example, gallium nitride and indium gallium nitride.

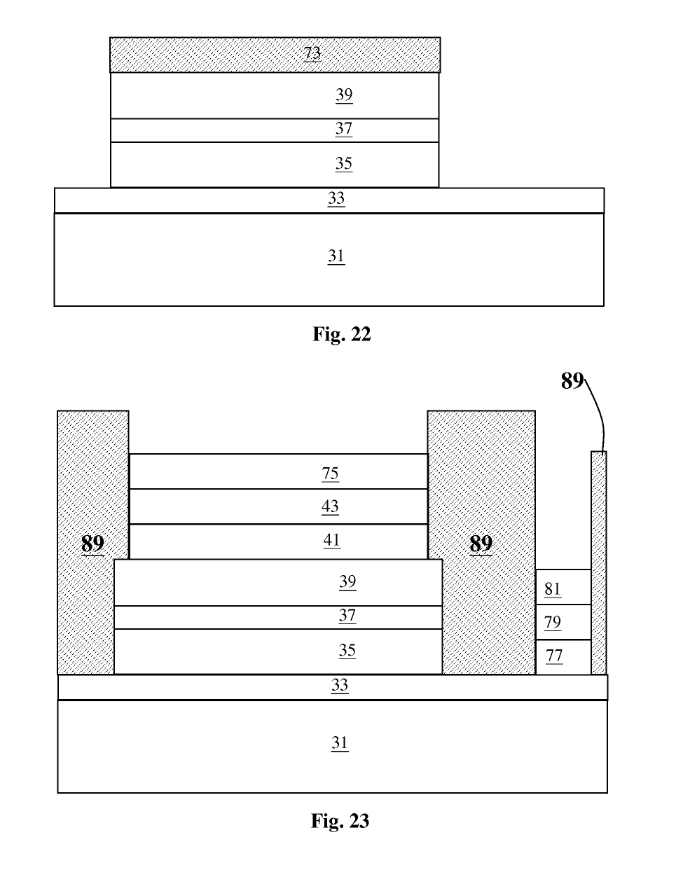

FIG. 21 shows a photoresist pattern 73 on the light-emitting structure. The photoresist pattern 73 is used to protect the light-emitting structure for forming light-emitting mesa structures by etching the unprotected portions of the light-emitting structure as shown in FIG. 22 and operation 17 of FIG. 2C. The photoresist pattern 73 is then removed, or stripped and a new pattern 89 applied for forming metal layers 41, 43, and 75 and temporary contact metal layers 77, 79, and 81 as shown in FIG. 23 and operation 27 of FIG. 2C.

The metal layer 41 is a contact metal layer formed over the doped layer 39. The contact metal layer 41 and temporary contact layer 77 in the temporary contact area are deposited concurrently. The reflective metal layer 43 and 79 are deposited concurrently, and bonding metal layers 75 and 81 are deposited concurrently.

The contact metal layer 41 and 77 may be nickel, an alloy of nickel, or some other metal. In one embodiment, the contact metal layer 41 (or 77) is a nickel/silver alloy. The contact metal layer 41 adheres well to the top layer of the light-emitting structure 30, and the contact metal layers 41 and 77 adhere well to the reflecting metal layers 43 and 79. A light reflecting layer 43 (or 79) may be a metal, such as aluminum, copper, titanium, silver, gold, alloys of these such as titanium/platinum/gold, or combinations thereof. The bonding metal material 75 and 81 may be a soft metal suitable for bonding with an adhesion metal layer on a bonding substrate. For example, the bonding metal may be a eutectic gold/tin alloy. The various metal layers may be formed by a physical vapor deposition (PVD) process or a chemical vapor deposition (CVD) process, or other applicable deposition processes in the art including electrodeposition or electroless deposition.

The partially fabricated LEDs may be individually tested and binned according to their responses to a test current in a wafer-based binning process in operation 28 of FIG. 2C. Electrodes are moved across the substrate from light-emitting mesa structure to light-emitting mesa structure, and a current driven across the bonding metal layer and the temporary contact. The light output at each light-emitting mesa structure is measured and binned. Defects and irregularities can be addressed at this stage before the light-emitting mesa structures are separated and packaged.

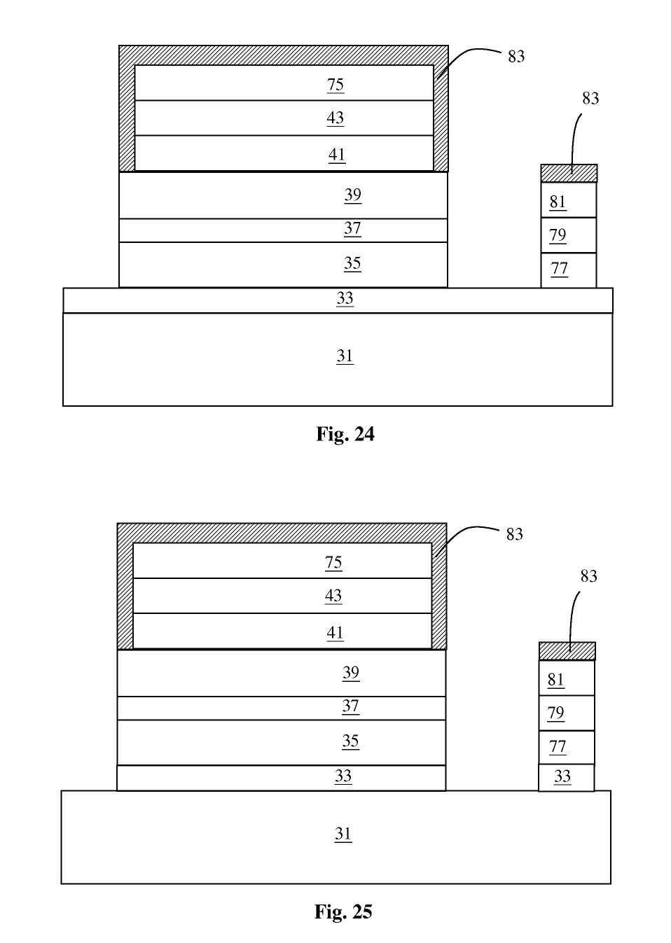

FIG. 24 shows various portions of the partially fabricated light-emitting mesa structure covered with photoresist pattern 83. Photoresist pattern covers the metal layers 41, 43, and 73. As shown, the photoresist pattern 83 covers not only the top surface, but also the sidewalls of the metal layers 41, 43, and 73. The photoresist pattern 83 also covers an exposed top surface portion of doped layer 39 such that only the sidewalls of layers 35, 37 and 39 are exposed.

Note that in FIG. 23, the metal layer surface may be the same size or smaller than the doped layer 39. If the metal layer surface is the same size as the doped layer 39, then the photoresist pattern 83 is optional because the metal layers can act as a hardmask for the subsequent etching process of buffer layer 33 and passivation of the light-emitting mesa structure sidewalls.

A portion of buffer layer 33 is then removed via an etching process, as shown in FIG. 25. A dry etch process that selectively removes undoped gallium nitride over the resist material and the sidewall material may be used. A bias may be used to direct the ions in the plasma toward the horizontal surface of the buffer layer 33. Additionally, reactive ion etch with inductively coupled plasma (ICP) may be used. The reactive ions may be boron chloride, chlorine, and/or argon.

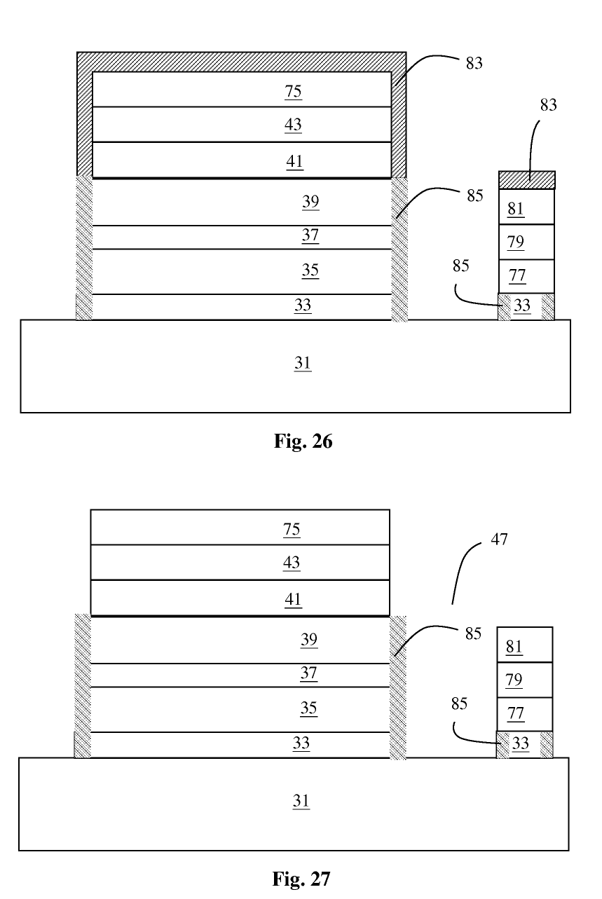

Next, the sidewalls of the light-emitting mesa structure are passivated as shown in FIG. 26 and in operation 19 of FIG. 2C. The passivation layer 85 may be formed using plasma bombardment or ion implantation. Details of the process are as described in association with FIG. 7. Note that in this operation a portion of the buffer layer 33 of the temporary contact may also be passivated.

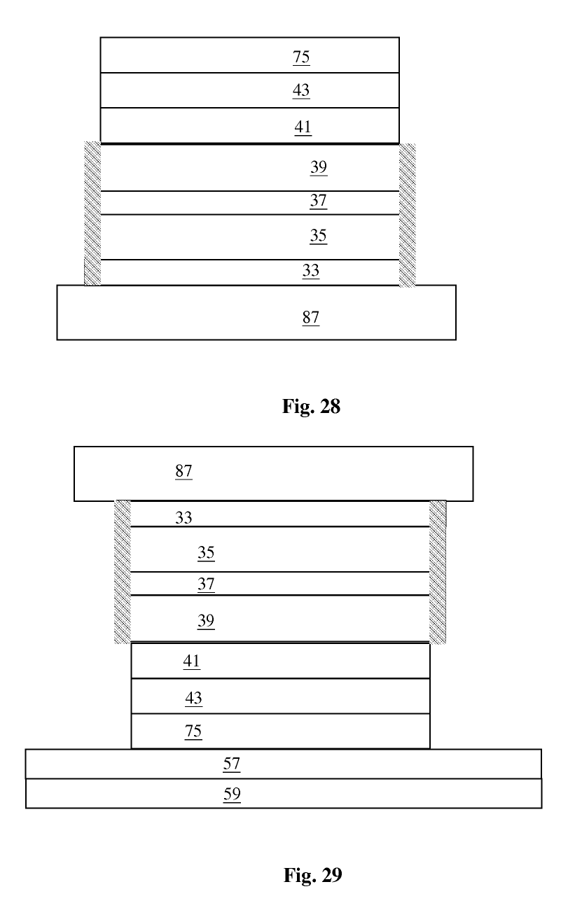

FIG. 27 shows the passivated light-emitting mesa structure without the photoresist pattern 83. The photoresist pattern 83 is removed by stripping or other applicable process. The growth substrate 31 is then optionally thinned by grinding, forming thinned substrate 87. The substrate 87 is then diced along the scribe lines 47 to separate the light-emitting mesa structures into LED dies, as shown in FIG. 28. Each LED die may be then flipped and mounted onto bonding substrate 59 having an adhesive metal layer 57 thereon, as shown in FIG. 29. The bonding metal layer 75 bonds to the adhesive metal layer 59 via a eutectic bond or a metal bond, as disclosed herein. In some embodiments, the LED dies are mounted onto the bonding substrate 59 according to the binning results. The LED dies have similar performances would be mounted together on the same bonding substrate. The LED dies can be packaged directly on the bonding substrate without being further separated into individual emitters. According to some embodiments, the LED dies are packaged into strips having groups of at least two LEDs.

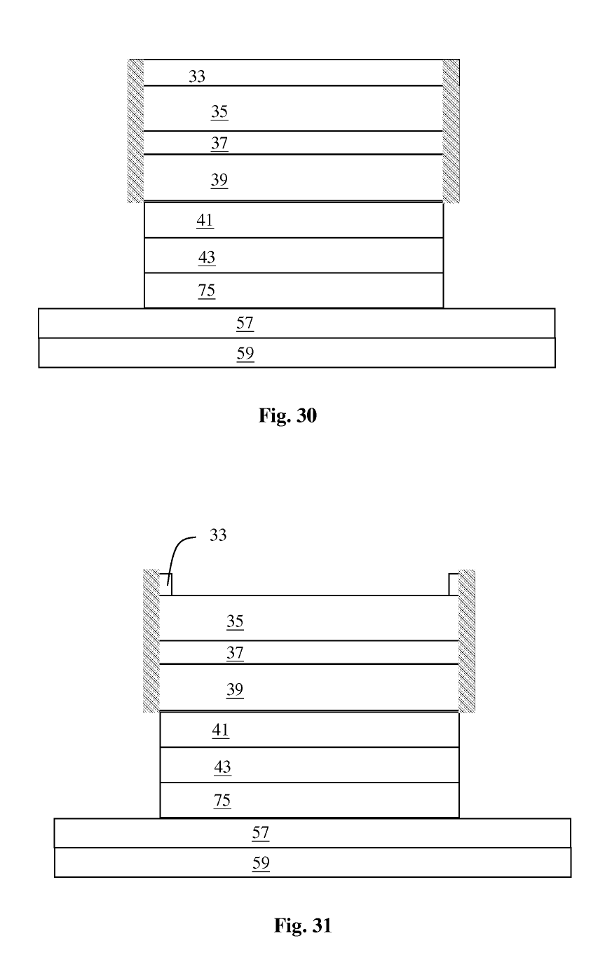

After the LED dies are bonded to the substrate, the growth substrate 87 is removed as shown in FIG. 30. Various methods are applicable to remove the growth substrate. In one example, an interface between the growth substrate and the buffer layer 33 is treated with electromagnetic radiation (for example, laser), which decomposes the material at the interface. This interface may be an undoped gallium nitride layer. The growth substrate, for example, sapphire, may be lifted off and removed as shown in FIG. 30.

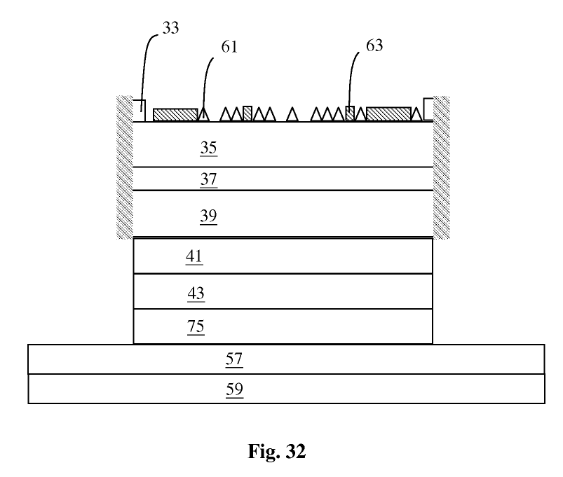

In some embodiments, the substrate mounted LED die has a portion of the buffer layer 33 removed, as shown in FIG. 31 and described in association with FIG. 13. The exposed surface of doped layer 35 is made rough and electrical contacts are formed on the surface as shown in FIG. 32 and described in association with FIG. 14.

The embodiments of FIGS. 20 to 32 result in an LED structure that includes a distinct bonding metal layer 75. As compared to the bonding metal layer 53 of FIG. 14, the bonding metal layer 75 of FIG. 32 does not cover the sidewalls of the contact metal layer 41 and reflective metal layer 43 because of the different use of photoresist patterns in these various embodiments. The different embodiments also vary in the process sequence when the light-emitting mesa structure sidewalls are passivated. One skilled in the art would recognize these and other possible combination of concepts in accordance with the present disclosure and be able to design a suitable process for specific LEDs.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A Light-Emitting Diode (LED) comprising:
a light-emitting structure, said structure comprising:
a first doped layer doped with a first impurity of a first conductivity type;
an active layer over the first doped layer;
a second doped layer over the active layer, the second doped layer doped with a second impurity of a second conductivity type opposite the first conductivity type; and
a passivation layer comprising a passivated portion of the active layer, wherein the passivated portion of the active layer is an entire edge portion of the active layer;
a contact metal layer electrically contacting and proximate to the second doped layer; and
a package substrate.

2. The LED of claim 1, wherein the passivation layer is at least 500 angstroms thick.

3. The LED of claim 1, further comprising a negative contact formed on the first doped layer and where the contact metal layer is a positive contact.

4. The LED of claim 1, wherein the first doped layer includes a rough surface on an opposite side from the active layer.

5. The LED of claim 1, further comprising a bonding metal layer contacting the contact metal layer, said bonding metal layer having a smaller area than the light-emitting structure.

6. The LED of claim 5, wherein the bonding metal layer completely covers the contact metal layer including the sidewalls.

7. The LED of claim 1, wherein the passivation layer completely cover the sidewalls of the first doped layer.

8. The LED of claim 1, wherein the passivation layer further comprises a passivated portion of the first doped layer, and a passivated portion of the second doped layer.

9. The LED of claim 1, wherein the passivation layer includes argon, nitrogen, oxygen, or krypton.

10. A method of fabricating a LED, comprising:
providing a growth substrate;
forming a light-emitting structure on the growth substrate, said structure comprising:
a first doped layer doped with a first impurity of a first conductivity type;
an active layer over the first doped layer; and
a second doped layer over the active layer, the second doped layer doped with a second impurity of a second conductivity type opposite the first conductivity type;
etching a plurality of streets into the light-emitting structure forming a plurality of light-emitting mesa structures with exposed sidewalls; and
passivating exposed sidewalls of the light-emitting mesa structures.

11. The method of claim 10, wherein the passivating exposed edges of the light-emitting mesa structures comprises:
performing ion implantation using nitrogen, argon, krypton, oxygen, silicon, selenium, beryllium, chlorine, boron, fluorine, or boron fluoride.

12. The method of claim 10, wherein the passivating exposed edges of the light-emitting mesa structures comprises:
bombarding the exposed edges of the light-emitting mesa structure with plasma.

13. The method of claim 12, wherein the plasma comprises nitrogen, argon, krypton, or oxygen.

14. The method of claim 10, wherein the passivating exposed edges of the light-emitting mesa structures is conducted at a substrate temperature less than about 150° C.

15. The method of claim 10, wherein the passivating exposed edges of the light-emitting mesa structures is conducted at about room temperature.

16. The method of claim 10, wherein the passivating exposed edges of the light-emitting mesa structures creates a passivation layer having average thickness at least about 500 angstroms.

17. The method of claim 10, further comprising:
forming a contact metal layer above the second doped layer; and
forming a bonding metal layer over the contact metal layer.

18. The method of claim 17, further comprising:
forming a temporary contact to the first doped layer;
applying a voltage to the bonding metal layer and to the temporary contact so that a light is emitted from the light-emitting mesa structure;
measuring the light emitted; and
binning the light-emitting mesa structure using the emitted light measurement.

19. The method of claim 18, further comprising:
dicing the growth substrate along the streets into a plurality of LED dies;
selecting the LED dies in the same bin;
attaching the bonding metal side of the LED dies in the same bin to a package substrate; and
removing the growth substrate.

20. The method of claim 19, wherein the removing the growth substrate comprises using laser to vaporize a portion of an undoped layer, said undoped layer disposed between the growth substrate and the first doped layer.
